(19) United States
(12) Patent Application Publication
(10) Pub. No.: US 2025/0336650 A1
(43) Pub. Date: Oct. 30, 2025

(54) APPARATUS AND METHOD OF FORMING CARBON-CONTAINING FILM ON SUBSTRATE

(71) Applicant: TOKYO ELECTRON LIMITED, Tokyo (JP)

(72) Inventors: Takaaki KATO, Nirasaki City, Yamanashi (JP); Miyako KANEKO, Nirasaki City, Yamanashi (JP); Naoko SUZUKI, Nirasaki City, Yamanashi (JP)

(21) Appl. No.: 18/704,259

(22) PCT Filed: Oct. 12, 2022
(86) PCT No.: PCT/JP2022/038081

§ 371 Date: Dec. 6, 2024

(30) Foreign Application Priority Data
Oct. 26, 2021 (JP) 2021-174853

(51) Int. Cl. H01J 37/32; C23C 16/27; C23C 16/455; C23C 16/458; C23C 16/505; H01L 21/02

(52) U.S. Cl. CPC H01J 37/32568; C23C 16/272; C23C 16/45565; C23C 16/4583; C23C 16/505; H01J 37/32082; H01J 2237/3321; H01L 21/02115

(57) ABSTRACT

An apparatus for forming a carbon-containing film on a substrate includes: a stage (lower electrode) provided inside a process container with the substrate placed thereon; and a gas shower head (upper electrode) positioned to face the stage inside the process container and provided to supply a film formation gas for the carbon-containing film into the process container while being connected to a radio-frequency power supply configured to supply radio-frequency power in a VHF or UHF band, wherein a distance between the stage and the gas shower head is set to a distance in a range of 1 time or more and 4 times or less of a skin depth of plasma of the film formation gas, which is formed by supplying the film formation gas from the gas shower head into the process container and supplying the radio-frequency power from the radio-frequency power supply to the upper electrode.

### TECHNICAL FIELD

The present disclosure relates to an apparatus and method of forming a carbon-containing film on a substrate.

### BACKGROUND

In the manufacturing process of semiconductor devices, when patterning a film formed on a substrate, i.e., a semiconductor wafer (hereinafter also referred to as “wafer”), a hard mask is often used to cover a portion that is not removed by etching. The discloser is considering using a film containing carbon (carbon-containing film), specifically, diamond-like carbon (DLC) film as the hard mask.

For example, Patent Document 1 discloses a technique for depositing diamond by heating a substrate in plasma from a hydrogen-containing gas using microwaves of 300 MHz or higher and supplying hydrocarbons to the substrate to decompose them. Further, Patent Document 2 discloses a technique for adjusting a hardness of a carbon film when forming a hard carbon film using a plasma CVD method by varying a direct current voltage (bias voltage) applied to a film formation substrate electrode.

### PRIOR ART DOCUMENTS

### Patent Documents

Patent Document 1: Japanese Laid-Open Publication No. 1986-003320
Patent Document 2: Japanese Laid-Open Publication No. H04-041672

The present disclosure provides a technique for forming a high-quality carbon-containing film using radio-frequency power in a VHF or UHF band.

### SUMMARY

The present disclosure provides an apparatus for forming a carbon-containing film on a substrate, which includes: a stage provided inside a process container and configured to serve as a lower electrode with the substrate placed thereon; and a gas shower head serving as an upper electrode positioned to face the stage inside the process container and provided to supply a film formation gas for the carbon-containing film into the process container, the gas shower head being connected to a radio-frequency power supply configured to supply radio-frequency power in a VHF or UHF band, wherein a gap distance between the stage and the gas shower head is set to a distance in a range of 1 time or more and 4 times or less of a skin depth of a plasma of the film formation gas, which is formed by supplying the film formation gas from the gas shower head into the process container and supplying the radio-frequency power from the radio-frequency power supply to the upper electrode.

According to the present disclosure, it is possible to form a high-quality carbon-containing film using radio-frequency power in a VHF or UHF band.

### BRIEF DESCRIPTION OF DRAWINGS

FIG. 1 is a configuration example of a film forming apparatus according to the present disclosure.

FIG. 2 is a schematic diagram of a parallel plate type plasma processing apparatus.

FIG. 3 is a diagram illustrating an ion energy distribution of plasma formed by varying bias radio-frequency power.

FIG. 4 is a Raman spectrum diagram of DLC films formed using the plasma.

FIG. 5 is a graph illustrating a variation in film stress and dry etching rate of the DLC films.

FIG. 6A is a first ion energy distribution diagram of plasma formed without supplying bias radio-frequency power.

FIG. 6B is a second ion energy distribution diagram of plasma formed without supplying bias radio-frequency power.

FIG. 6C is a third ion energy distribution diagram of plasma formed without supplying bias radio-frequency power.

FIG. 7A is a first Raman spectrum diagram of a DLC film formed using the plasma.

FIG. 7B is a second Raman spectrum diagram of a DLC film formed using the plasma.

FIG. 7C is a third Raman spectrum diagram of a DLC film formed using the plasma.

FIG. 8 is a first graph illustrating a relationship between plasma supply power and a film stress of the DLC film.

FIG. 9 is a second graph illustrating a relationship between the plasma supply power and the film stress of the DLC film.

FIG. 10 is a first graph illustrating a relationship between the plasma supply power and a film density of the DLC film.

FIG. 11 is a second graph illustrating a relationship between the plasma supply power and the film density of the DLC film.

FIG. 12 is a first graph illustrating a relationship between the plasma supply power and a film formation rate of the DLC film.

FIG. 13 is a second graph illustrating a relationship between the plasma supply power and the film formation rate of the DLC film.

FIG. 14 is a graph illustrating a relationship between the plasma supply power and a plasma density.

FIG. 15 is a graph illustrating a relationship between a plasma density and a skin depth.

### DETAILED DESCRIPTION

### <Film Forming Apparatus>

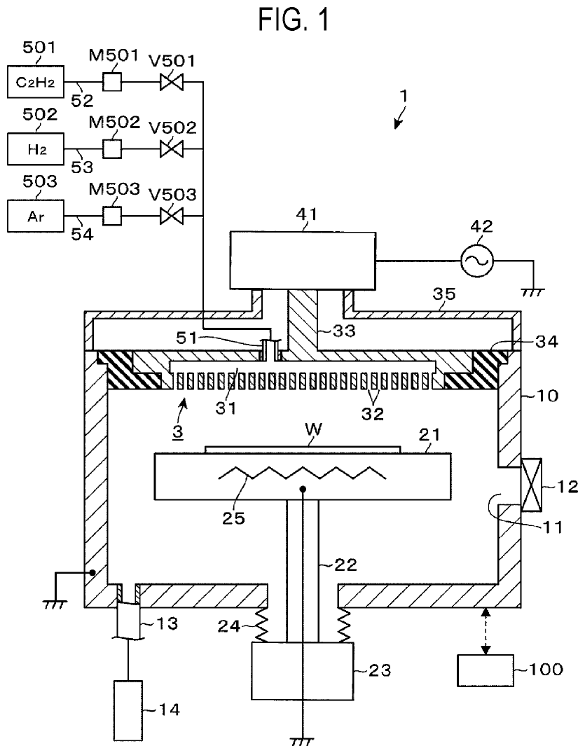

First, a configuration example of a film forming apparatus 1 according to an embodiment, which forms a carbon-containing film, specifically a DLC film, on a wafer W, will be described with reference to FIG. 1.

FIG. 1 is a longitudinal side view of the film forming apparatus 1 in this example. This film forming apparatus 1 is configured to continuously supply a C₂H₂ gas, a H₂ gas, and an argon (Ar) gas to a surface of the wafer W, and form a DLC film using a plasma CVD method.

The film forming apparatus 1 includes a grounded substantially cylindrical process container 10 made of aluminum or aluminum alloy. A loading/unloading port 11 is formed in a lateral side of the process container 10 to load or unload the wafer W between the process container 10 and a vacuum transfer chamber (not illustrated). The loading/unloading port 11 is configured to be opened or closed by a gate valve 12.

Further, an exhaust path 13 is connected to a bottom of the process container 10. A vacuum exhauster 14, which includes, for example, a pressure regulation valve and a vacuum pump, is connected to the exhaust path 13 so that an interior of the process container 10 is depressurized to a preset vacuum pressure. A film formation process of forming the DLC film on the wafer W is performed inside the process container 10.

A stage 21 for holding the wafer W substantially horizontally is provided inside the process container 10. The stage 21 is supported by a pillar 22 that extends vertically inside the process container 10. A lower side of the pillar 22 penetrates a bottom plate of the process container 10 and is connected to a lifter 23 provided below the process container 10. The lifter 23 has a function of raising or lowering the stage 21 into or out of the process container 10. A cover member 24 is provided around the pillar 22 protruding downward of the process container 10. The cover member 24 is positioned between the process container 10 and the lifter 23 to keep the interior of the process container 10 airtight.

A heater 25 is embedded in the stage 21 to heat the wafer W to a set temperature. In this example, a heating temperature of the wafer W is set in a range of 100 to 300 degrees C., for example, to 100 degrees C.

Further, lifting pins (not illustrated) are provided inside the process container 10 to vertically move the wafer W on the stage 21 while holding the wafer W. Such a vertical movement of the lifting pins enables transfer of the wafer W between the stage 21 and an external transfer mechanism (not illustrated).

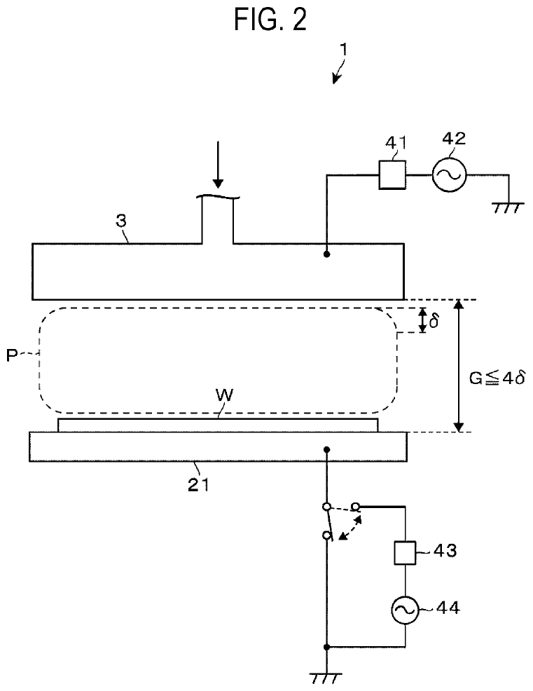

The stage 21 in this example is grounded and constitutes a lower electrode to plasmarize a film formation gas for the DLC film. Here, FIG. 1 illustrates an example where the lower electrode (stage 21) is not connected to a bias radio-frequency power supply that supplies bias radio-frequency power. In addition, as illustrated in FIG. 2 to be described later, the stage 21 may be configured to be connected to a bias radio-frequency power source 44 via a matcher 43.

Further, a flat disc-shaped gas shower head 3 is provided on a ceiling of the process container 10 to supply the film formation gas toward the wafer W. The gas shower head 3 is attached to the process container 10 via an insulating member 34.

An interior of the gas shower head 3 forms a diffusion space 31 in which the film formation gas diffuses. Further, a plurality of discharge holes 32 are formed in a bottom of the diffusion space 31 in a distributed manner to discharge the film formation gas toward the wafer W.

One end of a power feeding rod 33 is connected to an upper surface of the gas shower head 3 described above, and the other end thereof is connected to a matcher 41. In the example illustrated in FIG. 1, the matcher 41 is provided on an upper surface of a cover member 35 that covers an upper surface of the process container 10. The matcher 41 is connected to a radio-frequency power supply 42 that supplies radio-frequency power for plasma generation. With this configuration, the gas shower head 3 constitutes an upper electrode for plasmarizing the film formation gas.

As described above, the film forming apparatus 1 of the present disclosure is configured as a parallel plate type plasma processing apparatus including the gas shower head 3 serving as the upper electrode and the stage 21 serving as the lower electrode. The wafer W is placed in a space between the gas shower head 3 and the stage 21. By supplying gases such as a C₂H₂ gas and a H₂ gas to the space while supplying the radio-frequency power, these gases are ionized to form plasma.

The radio-frequency power supply 42 supplies the radio-frequency power in a frequency range of 30 MHz to 300 MHz which belongs to a VHF band, or in a frequency range of 300 MHz to 3 GHz which belongs to a UHF band. In the following example, a case of a configuration where the radio-frequency power of 90 MHz or 180 MHz can be supplied will be described.

A gas supply path 51 is connected at a downstream end thereof to the diffusion space 31 in the gas shower head 3. A C₂H₂ gas supply pipe 52, which is a supply flow path for the C₂H₂ gas serving as a raw material of the DLC film, a H₂ gas supply pipe 53, which is a supply flow path for the H₂ gas serving as a reaction gas, and an Ar gas supply pipe 54, which is a supply flow path for the Ar gas added for plasma generation, are joined at an upstream side of the gas supply path 51.

A C₂H₂ gas source 501 is connected to an upstream end portion of the C₂H₂ gas supply pipe 52 in which a flow rate adjuster M501 and a valve V501 are provided in this order from the upstream side. Further, a H₂ gas source 502 is connected to an upstream end portion of the H₂ gas supply pipe 53 in which a flow rate adjuster M502 and a valve V502 are provided in this order from the upstream side. Further, an Ar gas source 503 is connected to an upstream end portion of the Ar gas supply pipe 54 in which a flow rate adjuster M503 and a valve V503 are provided in this order from the upstream side.

A mixture gas of the C₂H₂ gas, the H₂ gas, and the Ar gas is introduced into the diffusion space 31 in the gas shower head 3 via the gas supply path 51. Subsequently, the film formation gas is supplied into the process container 10 via the discharge holes 32.

The film forming apparatus 1 having the above-described configuration includes a controller 100. The controller 100 is constituted with a computer including a storage storing a program, a memory, and a CPU. The program incorporates instructions (steps) that are executed by the controller 100 to output control signals to each component of the film forming apparatus 1 and control the supply or cutoff of each gas as well as the supply of the radio-frequency power, thus executing the film formation process of forming the DLC film. The program is stored in the storage of the computer, such as a flexible disk, a compact disk, a hard disk, a magneto-optical (MO) disk, or a non-volatile memory, is read from the storage, and is installed in the controller 100.

### <Film Formation Process Operation>

An operation of the film forming apparatus 1 having the configuration described above will be briefly described.

First, the gate valve 12 is opened, and the wafer W is loaded via the loading/unloading port 11 by a transfer mechanism provided inside the vacuum transfer chamber (not illustrated). The wafer W thus loaded is transferred from the transfer mechanism to the stage 21 by the lifting pins (not illustrated) and is placed on an upper surface of the stage 21 (in an operation of placing the wafer W on the stage 21). Subsequently, when the transfer mechanism is retracted from the interior of the process container 10 and the gate valve 12 is closed, the interior of the process container 10 is evacuated by the vacuum exhauster 14 so that an internal pressure of the process container 10 is adjusted to a preset pressure. Further, the wafer W is heated to 100 degrees C. described above by the heater 25.

Then, the supply of the film formation gas is initiated and the supply of the radio-frequency power from the radio-frequency power supply 42 is also initiated. Further, in the case where the bias radio-frequency power is supplied from the bias radio-frequency power supply 44 connected to the stage 21 as in the example illustrated in FIG. 2, the supply of the bias radio-frequency power is also initiated.

Through the above-described operation, the film formation gas supplied into the process container 10 is converted into plasma, and the DLC film is formed on the surface of the wafer W by ions contained in the plasma (in an operation of forming a carbon-containing film on a substrate).

In this way, by continuing film formation with the film formation gas plasmarized for a preset period of time, the DLC film having a desired film thickness is formed. Subsequently, the supply of the radio-frequency power is terminated, and the supply of the film formation gas is also stopped. Thereafter, the wafer W is unloaded from the process container 10 in the reverse order of the loading operation as described above, and the apparatus waits for the loading of a next wafer W.

### <Control of Film Quality of DLC Film>

In the film formation of the DLC film using the film forming apparatus 1 configured as above, it is desirable to perform the film formation process with a relatively high film formation rate from the viewpoint of production efficiency. From this viewpoint, the inventors focused on radio-frequency power in a VHF or UHF band as a frequency range where a higher plasma density is obtained than a frequency (13.56 MHz) used in the related art.

Further, in a case where the DLC film is used as a hard mask, the DLC film may have a high etching selectivity. From this viewpoint, a film density is regarded as an index for evaluating the etching selectivity of the DLC film. In other words, since a DLC film with a high film density has a low impurity content and a bonding state thereof also approximates diamond, it tends to have a high etching resistance. A DLC film with a film density of 1.8 g/cm³ or higher, specifically 2.0 g/cm³ or higher, may be practically evaluated as exhibiting sufficiently high etching resistance.

Taking these matters into consideration, the inventors have studied film formation conditions in which a DLC film with good film quality and high productivity is obtained. As a result, it was found that, by merely supplying radio-frequency power in a VHF or UHF band at a high output to plasmarize the film formation gas, a high-density DLC film may not be obtained at a high film formation rate with the supply of the radio-frequency power. In order to obtain an optimal film formation condition, it is necessary to select appropriate control variables and specify suitable control variables based on a sufficient understanding of a film formation mechanism for the DLC film, or characteristics of plasma which vary depending on a method of supplying the radio-frequency power.

The inventors understand that ions in the plasma of the film formation gas are important for the formation of the DLC film with a high film density. In other words, by supplying ions from the film formation gas with an appropriate ion energy at a high density, it is possible to increase the film density of the DLC film. On the other hand, radical components contained in the plasma become a factor leading to a decrease in the film density of the DLC film.

Based on such findings, the DLC film was formed using the film forming apparatus 1 having almost the same configuration as that described with reference to FIG. 1, and the distribution of ion energy in the plasma and the characteristics of the DLC film were measured by varying the film formation conditions.

FIG. 2 schematically illustrates the film forming apparatus 1 (parallel plate type plasma processing apparatus) of FIG. 1. The film formation conditions include (i) the supply of the power from the radio-frequency power supply 42, (ii) whether or not the bias radio-frequency power is supplied, (iii) when the bias radio-frequency power is supplied, the supplied power, and (iv) varying a gap distance (hereinafter also referred to as “electrode gap”) between the stage 21 and the gas shower head 3. The electrode gap may be adjusted by raising and lowering the stage 21.

Further, as an index for evaluating an action of the electrode gap, the inventors focused on a skin depth, which is a measure of how the radio-frequency power supplied from the radio-frequency power supply 42 enters a plasma P. The skin depth for the plasma P may be calculated using the following equation (1).

$$δ = ( c / {ω}_{p} ) \qquad ( 1 )$$

where, δ is the skin depth, c is the speed of light, and ωₚ is an electron plasma frequency which is represented by the following equation (2).

$${ω}_{p} = {( {n}_{e} {e}^{2} / m ε0 )}^{1 / 2} \qquad ( 2 )$$

where, n_{c} is an electron density, e is an electron charge, m is the mass of an electron, and ε₀ is a permittivity of vacuum. The electron density in the plasma may be measured using a Langmuir probe or the like.

### <Film Quality Control Experiment 1: Supply or Non-Supply of Bias Radio-Frequency Power>

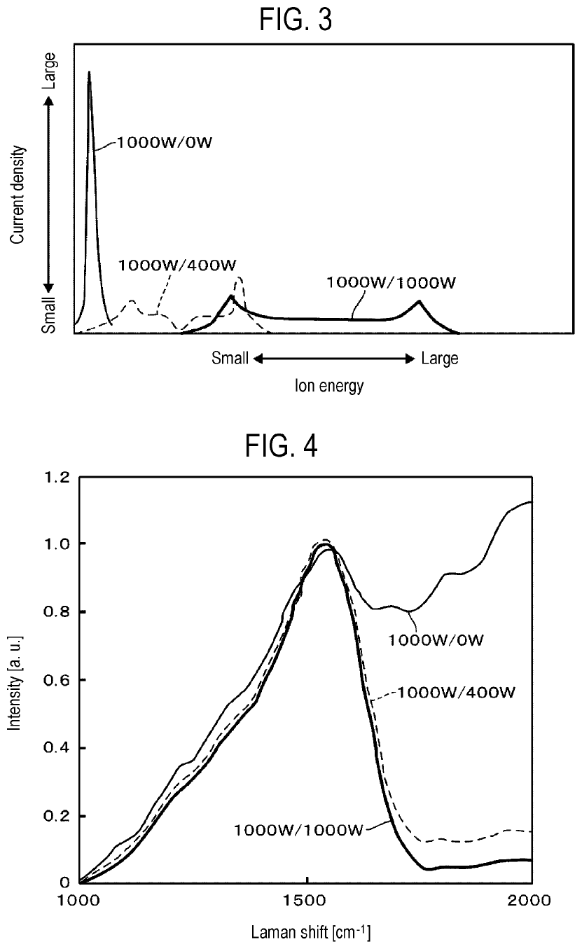

First, (ii) in a case when the bias radio-frequency power is supplied and in a case when the bias radio-frequency power is not supplied, and in the former case (iii) the effect when the bias radio-frequency power is changed will be described with reference to FIGS. 3 to 5.

As described above, the DLC film is formed using ions in the plasma of the film formation gas. Even in the radio-frequency power of 13.56 MHz in the related art, when the film formation is performed using ions, an operation of supplying the bias radio-frequency power to the stage 21 and allowing the ions in the plasma to be drawn to the wafer W is generally performed.

Therefore, the bias radio-frequency power (having 13.56 MHz in a range of 3 to 30 MHz) was changed to the case of supplying the bias radio-frequency power (Experimental Example 1-1:1,000 W, Experimental Example 1-2:400 W) and then to the case where the bias radio-frequency power is not supplied (Experimental Example 1-3:0 W), the density of ion energy in the plasma was measured, a structural analysis of the obtained DLC film was performed, and a film stress and a dry etching rate were measured.

As parameters of the film formation process, the internal pressure of the process container 10 was set to 20 mTorr (2.67 Pa), a supply flow rate of the C₂H₂ gas was set to 20 sccm, a supply flow rate of the Ar gas was set to 180 sccm, the heating temperature of the wafer W was set to 100 degrees C., a frequency of the radio-frequency power supplied from the radio-frequency power supply 42 was set to 180 MHz, a supply power (hereinafter also referred to as “plasma supply power”) was set to 1,000 W, and an electrode gap G was set to 30 mm (a ratio of G to the plasma skin depth δ of 7 mm=4.5).

The ion energy density was measured using a multigrid type analyzer, multimeter (model 7352A manufactured by ADCMT Corporation), and a source meter (model 2410 manufactured by KEITHREY Corporation), and a structure of the obtained DLC film was analyzed using Raman spectroscopy. The film stress was measured using a FLX type stress gauge (manufactured by Toho Technology Corporation), and the dry etching rate was measured based on a variation in the film thickness of the DLC film before and after dry etching with a CF-based gas.

FIG. 3 illustrates a distribution of ion energy in the plasma when the bias radio-frequency power (hereinafter also referred to as “bias power”) is varied. In FIG. 3, the horizontal axis represents a relative magnitude of ion energy and the vertical axis represents a relative magnitude of current density. In FIG. 3, the thick solid line represents the ion energy distribution in Experimental Example 1-1, the dashed line represents the ion energy distribution in Experimental Example 1-2, and the thin solid line represents the ion energy distribution in Experimental Example 1-3. In each Experimental Example of FIG. 3, values of the plasma supply power and values of the bias power are written in this order.

According to the results illustrated in FIG. 3, in Experimental Example 1-1 where the bias radio-frequency power was set to 1,000 W, the average value of ion energy in the plasma is higher compared to the other examples (Experimental Examples 1-2 and 1-3), and the ion energy distribution is the widest and has two relatively small peaks.

On the other hand, in Experimental Example 1-3 where no bias radio-frequency power was supplied, the average value of ion energy in the plasma is relatively low. Further, the ion energy distribution has a sharp unimodal shape in which ions in a relatively narrow range of ion energy are concentrated around a single peak.

Further, in Experimental Example 1-2 where the bias radio-frequency power was set to 400 W, both the average value of ion energy and the width of the ion energy distribution are between those in the other examples (Experimental Examples 1-1 and 1-3), respectively. In addition, the ion energy distribution includes two relatively small peaks and has a shape similar to that in Experimental Example 1-1.

Subsequently, the results (Raman spectrum) of Raman spectroscopy for the DLC films formed under the conditions of Experimental Examples 1-1 to 1-3 are illustrated in FIG. 4. In FIG. 4, the horizontal axis represents a Raman shift illustrating a difference in wave number between incident light and scattered light, and the vertical axis represents an intensity of the scattered light (arbitrary unit). As in FIG. 3, the thick solid line represents the Raman spectrum in Experimental Example 1-1, the dashed line represents the Raman spectrum in Experimental Example 1-2, and the thin solid line represents the Raman spectrum in Experimental Example 1-3.

In the Raman spectrum, carbon atoms with a diamond structure exhibit significant scattering in the vicinity of a region having a Raman shift wave number of 1,500 cm⁻¹. Thus, a Raman spectrum concentrated around this wave number may be evaluated as a high-quality DLC film close to a diamond structure.

From this viewpoint, referring to FIG. 4, in Experimental Example 1-3 (the bias radio-frequency power: 0 W) represented by the thin solid line, the scattered light was detected at a high intensity in a radio frequency region (hereinafter also referred to as “base region”) other than the region having the Raman shift wave number of 1,500 cm⁻¹. Since this region contains a relatively large number of carbon atoms with structures other than the diamond structure and a relatively large number of impurities, a polymer-like carbon-containing film (PLC) may be evaluated to have been formed rather than the DLC film.

On the other hand, the Raman spectra in Experimental Examples 1-1 and 1-2 exhibit a spectrum shape concentrated in the vicinity of the region having the Raman shift wave number of 1,500 cm⁻¹, compared to Experimental Example 1-3. From this viewpoint, DLC films with good film quality, which contain a relatively small content of impurities and a large number of carbon atoms with the diamond structure, may be evaluated to have been obtained. In particular, the result of Experimental Example 1-1 shows that the intensity of the scattered light is kept low in the base region.

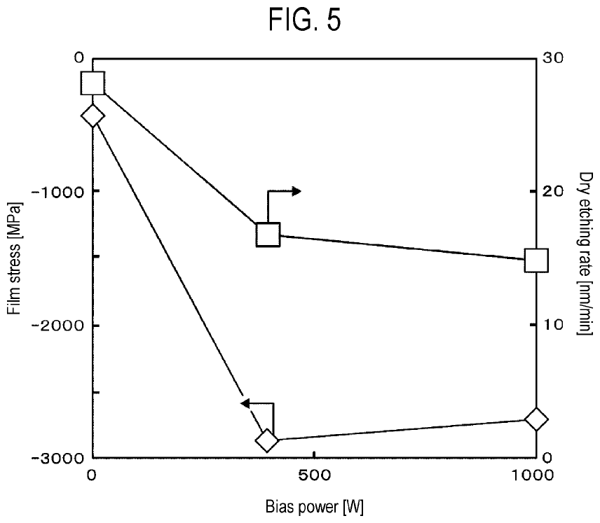

FIG. 5 illustrates measurement results obtained by measuring a film stress and a dry etching rate for the DLC films obtained in Experimental Examples 1-1 to 1-3. In FIG. 5, the horizontal axis in FIG. 5 represents the bias radio-frequency power, the left vertical axis represents the film stress of the DLC films, and the right vertical axis represents the dry etching rate. In FIG. 5, the measurement results of the film stress are represented by square plots, and the measurement results of the dry etching rate are represented by diamond plots.

There is a tendency that the lower a value of the film stress (the larger the absolute value), the tighter, denser, and more etching resistant DLC film is obtained.

As evaluated from the measurement results from the Raman spectrum in FIG. 4, the DLC films obtained in Experimental Examples 1-1 and 1-2, where higher quality DLC films were formed, exhibit a high film density and low dry etching rate. In contrast, the DLC film obtained in Experimental Example 1-3 exhibits a small absolute value of film stress and a high dry etching rate.

Based on the results of Experimental Examples 1-1 to 1-3 observed with reference to FIGS. 3 to 5, it can be said that, compared to the case of not supplying the bias radio-frequency power (Experimental Example 1-3), the case of supplying the bias radio-frequency power at a sufficiently high level (Experimental Examples 1-1 and 1-2) provides high-quality DLC films.

Therefore, it is believed that, under the condition of supplying the bias radio-frequency power, by increasing the plasma supply power from the radio-frequency power supply 42, it is possible to form a high-quality DLC film at a high film formation rate.

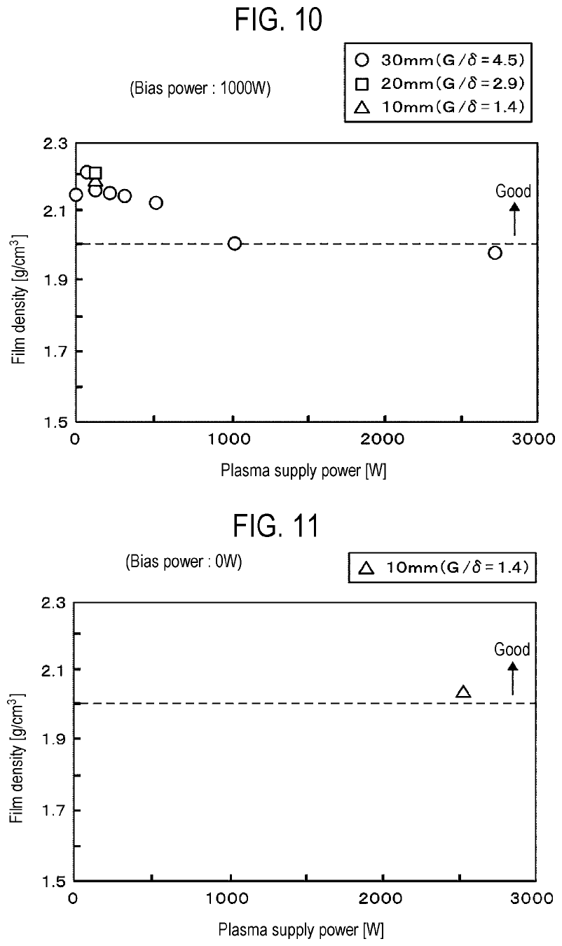

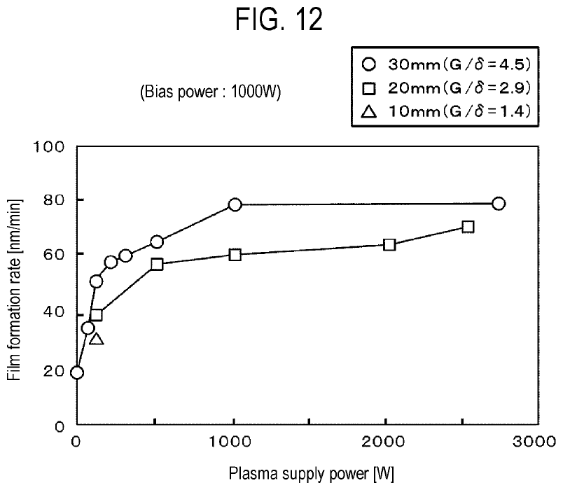

However, as represented by circular plots in FIG. 10 to be described later, when the plasma supply power is increased under a condition that the bias radio-frequency power has a fixed value of 1,000 W, the film density of the DLC film gradually decreases and falls below a target value of 2.0 g/cm³. In addition, as represented by circular plots in FIG. 12 to be described later, there is a tendency that the film formation rate of the DLC film gradually increases with an increase in plasma supply power, and then saturates.

As will be appreciated from the foregoing, under the condition that the radio-frequency power is supplied, as the radio-frequency plasma supply power increases in the VHF band, it has been confirmed that there is not a simple relationship of obtaining a high-density DLC film at a high film formation rate.

Next, the effect of a case when the film formation conditions are varied under the condition that no bias radio-frequency power is supplied will be described in detail.

### <Film Quality Control Experiment 2: Supply of Single Frequency>

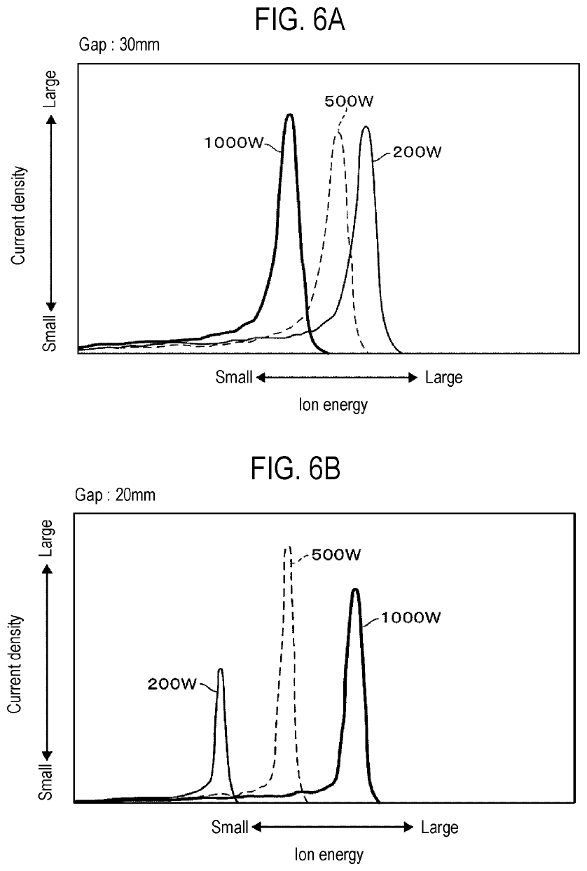

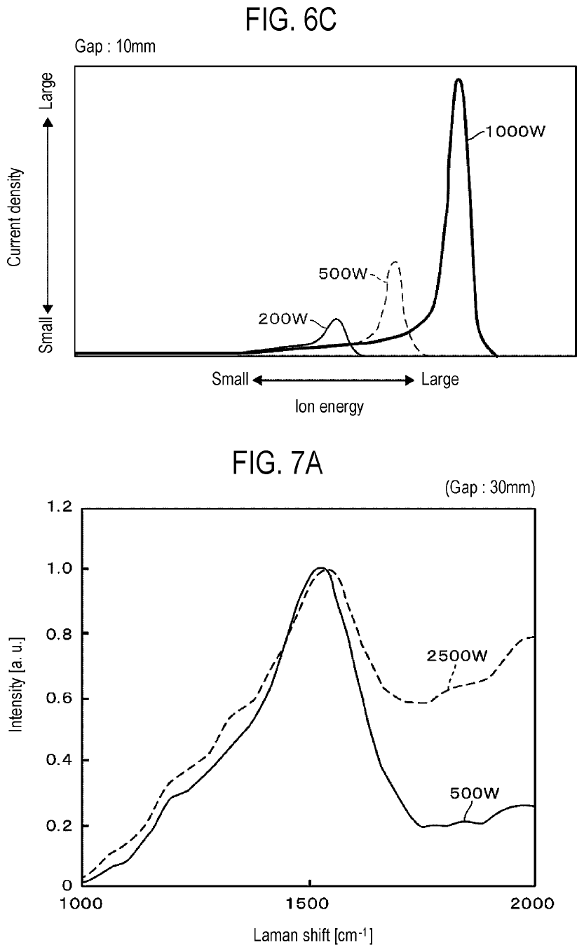

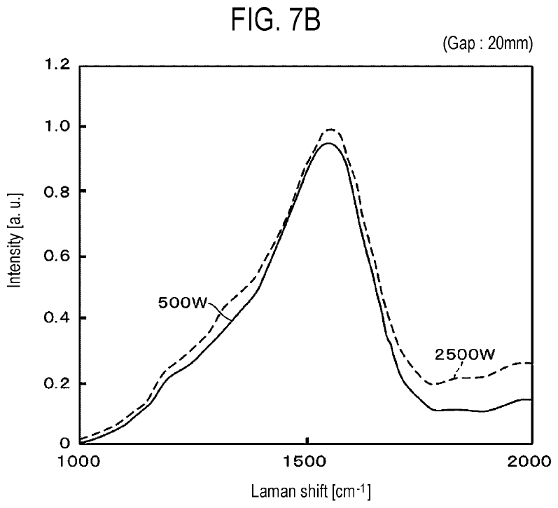

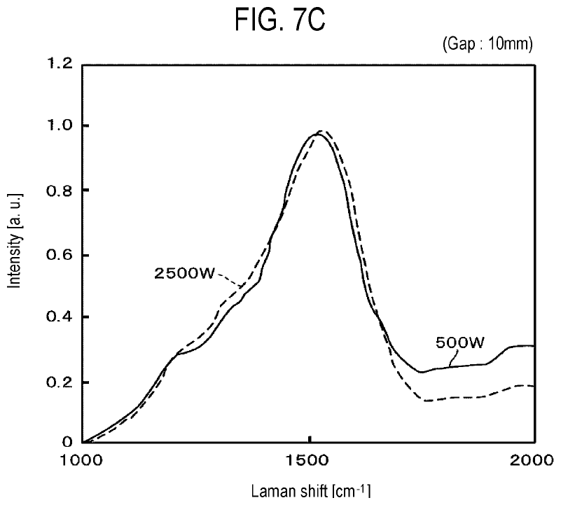

FIGS. 6A to 7C illustrate measurement results of the distribution of ion energy in the plasma and the Raman spectrum of the DLC film when varying the power supplied from the radio-frequency power supply 42 in the condition (i) above (hereinafter also referred to as a “supply of single frequency” from the radio-frequency power supply 42) under the condition that (iv) the electrode gap is changed without supplying the bias radio-frequency power in the condition (ii) above.

FIGS. 6A to 6C illustrate the measurement results of the ion energy distribution when varying the plasma supply power from the radio-frequency power supply 42 to 1,000 W, 500 W, and 200 W under conditions that the electrode gap G is 30 mm (G/δ=4.5), 20 mm (G/δ=2.9), and 10 mm (G/δ=1.4). The other process conditions are the same as in Experimental Example 1-3 described above.

In each of the drawings, the horizontal and vertical axes are the same as in FIG. 3, with the thick solid line representing the plasma supply power of 1,000 W, the dashed line representing the plasma supply power of 500 W, and the thin solid line representing the ion energy distribution of 200 W.

Further, FIGS. 7A to 7C illustrate the Raman spectrum of the DLC film formed by varying the plasma supply power from the radio-frequency power supply 42 to 500 W and 2,500 W under the conditions that the electrode gap G is 30 mm, 20 mm, and 10 mm. The other process conditions are the same as in Experimental Example 1-3 described above.

In each of the drawings, the horizontal and vertical axes are the same as in FIG. 4, with the thick solid line representing the Raman spectrum with the plasma supply power of 500 W and the dashed line representing the Raman spectrum with the plasma supply of 2,500 W.

The ion energy distribution under the respective conditions illustrated in FIGS. 6A to 6C all exhibit a sharp unimodal shape with ions concentrated in a relatively narrow ion energy range. On the other hand, the behavior of a variation in ion energy distribution when varying the plasma supply power from the radio-frequency power supply 42 depends on the size of the electrode gap.

In other words, in FIG. 6A with the electrode gap G=30 mm, as the plasma supply power is increased in the order of 200 W→500 W→1,000 W, a peak position of the ion energy distribution gradually shifts toward lower energy. At this time, a peak height of the ion energy distribution does not vary significantly with a variation in the magnitude of the plasma supply power.

On the other hand, in FIG. 6B (with the electrode gap G=20 mm) and FIG. 6C (with the electrode gap G=10 mm), the peak position of the ion energy distribution shifts toward higher energy in response to an increase in plasma supply power.

Further, in FIG. 6B, the peak height of the ion energy distribution is highest at the plasma supply power of 500 W, followed by 1,000 W, and then lowest at 200 W. In contrast, FIG. 6C illustrates a tendency of the peak height gradually increasing with an increase in plasma supply power.

As above, in the case of supplying the single frequency without supplying the bias radio-frequency power, a unimodal ion energy distribution is obtained. On the other hand, the behavior of a variation in ion energy distribution corresponding to the variation in plasma supply power depends on the size of the electrode gap.

Further, the film quality of the DLC film formed under each condition also varies based on the variation in ion energy distribution.

That is, in FIG. 7A (with the electrode gap G=30 mm), the DLC film formed under the condition that the plasma supply power is low (500 W) exhibits a low intensity of scattered light in the base region of the Raman spectrum, so that a high-quality DLC film was obtained.

On the other hand, in FIG. 7B (with the electrode gap G=20 mm), the DLC film formed under the condition that the plasma supply power is high (2,500 W) exhibits a significant decrease in the intensity of scattered light in the base region of the Raman spectrum. Further, in FIG. 7C (with the electrode gap G=10 mm), the DLC film formed under the condition that the plasma supply power is high (2,500 W) exhibits a low intensity of scattered light in the base region of the Raman spectrum, compared to the case where the plasma supply power is low (500 W).

### <Overall Evaluation>

From the examples illustrated in FIGS. 7B and 7C, it could be confirmed that there are conditions under which a DLC film with good film quality is obtained as the plasma supply power is increased. This differs from the behavior of the circular plots in FIG. 10 where the film density of the DLC film gradually decreases when supplying the bias radio-frequency power and increasing the plasma supply power. In other words, the results in FIGS. 7B and 7C indicate that, in the case where the electrode gap is included in the control variables (in the condition (iv) above), there may be film formation conditions under which a high film formation rate is obtained in forming a DLC film with good film quality.

As a premise for obtaining such film formation conditions, the inventors thought that it is important to adjust the ion energy distribution, as illustrated in FIGS. 3 and 6A to 6C. In other words, the inventors thought that it is possible to obtain a high-quality DLC film even with a variation in plasma supply power by forming plasma so that the peak of the ion energy distribution corresponds to appropriate ion energy.

Further, according to the experimental results in FIGS. 6A to 6C, it can be understood that the adjustment of the electrode gap (in the condition (iv) above) is one of the control variables for controlling the peak position of the ion energy distribution.

In particular, the plasma skin depth becomes smaller in the VHF or UHF band where the frequency is higher than the frequency (for example, 13.56 MHZ) used in the related art. At this time, when the electrode gap is larger than the skin depth, plasma of sufficient size having an ion energy distribution, in which a high-quality film is obtained, may not be generated between the stage 21 and the gas shower head 3.

Therefore, the inventors focused on a ratio of the gap distance (the electrode gap) between the stage 21 serving as the lower electrode and the gas shower head 3 serving as the upper electrode to the skin depth of the plasma formed between these electrodes. By adjusting this ratio in an appropriate range, it is possible to obtain a high-quality DLC film while keeping a high film formation rate.

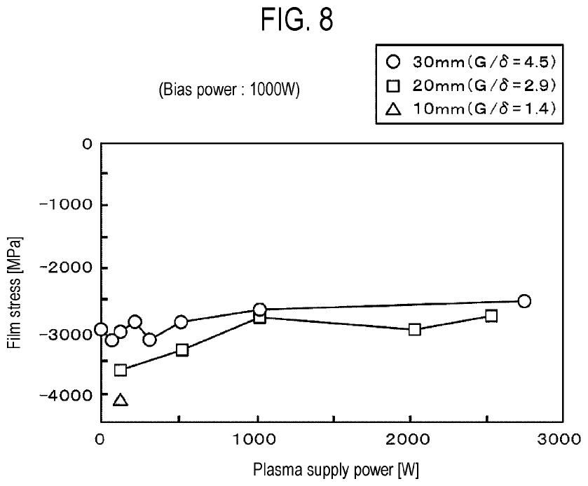

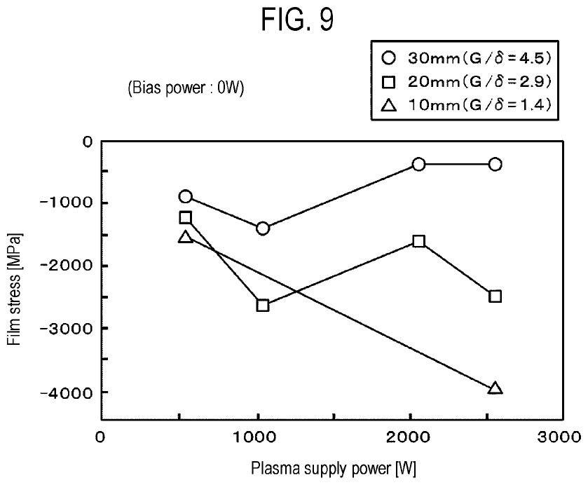

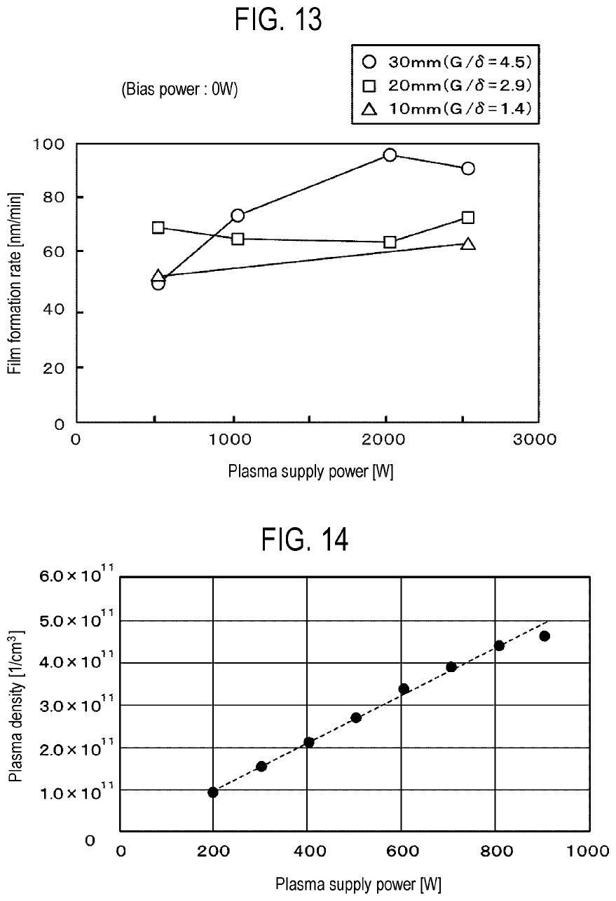

FIGS. 8 to 13 illustrate various characteristics of the DLC film formed under the condition of the variation in the plasma supply power with the electrode gap as a parameter, in the case where the bias radio-frequency power is supplied (FIGS. 8, 10, and 12) and in the case where the bias radio-frequency power is not supplied (FIGS. 9, 11, and 13). FIGS. 8 and 9 illustrate a variation in film stress of the DLC film, and FIGS. 10 and 11 illustrate a variation in film density of the DLC film. Hereinafter, a case where a target value of the film density of the DLC film as described above is set to 2.0 g/cm³ or higher will be described. The dashed line in FIGS. 10 and 11 represents the target value, and points plotted above the dashed line represent that each DLC film has a film density satisfying the target value. Further, FIGS. 12 and 13 illustrate a variation in film formation rate of the DLC film.

As indicated by circular plots in FIG. 8, for example, in the case where the bias radio-frequency power is supplied and the electrode gap is set to 30 mm (G/δ=4.5), when the plasma supply power is increased, the absolute value of the film stress of the DLC film tends to gradually decrease, eventually to be saturated. Further, as indicated by the circular plots in FIG. 10, the variation in the film density of the DLC film under similar conditions exhibits a behavior corresponding to the variation in film stress. In other words, when the plasma supply power is increased, the film density of the DLC film tends to gradually decrease, eventually to be saturated. Further, when the plasma supply power is 1,000 W or higher, the film density of the DLC film is lower than the target value (2.0 g/cm³).

Subsequently, in a single frequency example, only data about the film density of the DLC film is obtained under the conditions that the electrode gap is 10 mm (G/δ=1.4) and the plasma supply power is 2,500 W (FIG. 11). As illustrated in FIG. 11, the film density of the DLC film formed under these conditions exceeds the target value.

Here, the variation in the film stress in FIG. 9 illustrating three comparable electrode gaps is considered. When the plasma supply power is 2,500 W, the absolute value of the film stress tends to increase as the electrode gap decreases. In the DLC film plotted in FIG. 11, the fact that the film density exceeds the target value may be evaluated as a result of reflecting the state of the film stress.

Further, as illustrated in FIGS. 12 and 13, it was confirmed that, in both the case where the bias radio-frequency power is supplied and the case of the single frequency, the film formation rate tends to increase as the plasma supply power increases even at any electrode gap.

The following is a brief summary on the above description. According to the experimental results illustrated in FIG. 9, in the case of the single frequency, it is desirable to set the electrode gap G to 20 mm and 10 mm and to set the ratio G/δ of the electrode gap G to the plasma skin depth δ to 2.9 or 1.4 in a range of 1 or more and 4 or less when the plasma supply power is in the range of 1,000 W or higher and 2,500 W or lower. Thus, compared to the case where the electrode gap G is 30 mm, by increasing the absolute value of the film stress, it is possible to obtain a DLC film with a relatively high film density. In particular, it was confirmed that the film density reaches 2.0 g/cm³ as the target value when the value of G/δ is 1.4 (G=10 mm) in a range of 1 or more and 2 or less (FIG. 11).

Further, according to the experimental results illustrated in FIG. 8, in the case where the bias radio-frequency power is supplied, it is desirable to set the electrode gap G to 20 mm and to set the ratio G/δ of the electrode gap G to the plasma skin depth δ to 2.9 in the range of 1 or more and 4 or less, specifically in a range of 2 or more and 3 or less when the plasma supply power is in the range of 1,000 W or more and 2,500 W or less. Based on the measurement results of film stress illustrated in FIG. 8, it is estimated that, by increasing the absolute value of the film stress, it is possible to obtain a DLC film with a relatively high density, compared to the case where the electrode gap G is 30 mm.

In addition, based on the experimental results described with reference to FIGS. 3 and 4, it is desirable to set the bias radio-frequency power to a value in a range of 400 W or more and 1,000 W or less.

Further, while the case where the skin depth δ is 7 mm has been described above, an allowable range of the skin depth δ is not limited thereto. The ratio G/δ of the electrode gap G to the plasma skin depth δ may be appropriately selected in the range of 1 or more and 4 or less. For example, when the electrode gap G ranges from 6 mm to 32 mm and the skin depth δ ranges from 5.3 mm to 7.8 mm, each condition may be selected so that the ratio G/δ of the electrode gap G to the plasma skin depth δ is in the range of 1 or more and 4 or less.

Here, the basis for setting the above-described range of the skin depth (8:5.3 to 7.8 mm) will be described. It is known that the skin depth in the VHF or UHF band converges to a substantially constant value in the pressure range of 2 to 200 mTorr (0.27 to 26.7 Pa) in which the formation of the DLC film is performed. Therefore, by supplying the radio-frequency power in the VHF band in the pressure range to form plasma and specifying the electron density, it is possible to specify the range of the plasma skin depth based on Equations (1) and (2) above.

Therefore, under an atmosphere in which an Ar gas is supplied (a supply flow rate of the Ar gas is 450 sccm), the plasma density (Ar ion density) was measured by setting the internal pressure of the process container 10 to 100 mTorr (13.3 Pa) and the electrode gap G to 30 mm while varying the plasma supply power in a range of 200 W to 900 W. The Ar ion density is approximately equal to the electron density in plasma kept in an equilibrium state. Thus, the skin depth δ may be calculated based on Equations (1) and (2) above.

FIG. 14 illustrates measurement results of the plasma density with respect to the plasma supply power. A regression equation was obtained based on the measurement results. A relationship between a plasma density Y and the plasma supply power could be expressed by Equation (3) below.

$$Y = 6 \times {10}^{8} X - 9 \times {10}^{9} ( {R}^{2} = 0.9931 ) \qquad ( 3 )$$

Further, based on Equation (3) above, the plasma density calculated when the plasma supply power is 2,500 W, is approximately 1.491×10¹² [1/cm³].

Here, in the above measurements, it was confirmed that the plasma density is saturated around 900 W. This is presumed to be due to the fact that all the supplied power is not absorbed by the plasma but leaks into, for example, a space below the stage 21. Further, the same tendency was observed even when the electrode gap G was set to 30 mm or less. Further, when another gas (for example, a hydrocarbon gas CₓH_{y}) is mixed with the Ar gas, the plasma density tends to decrease. Therefore, it may be considered from this fact and Equation (3) that the upper limit of the plasma density is approximately 1.0×10¹² [1/cm³].

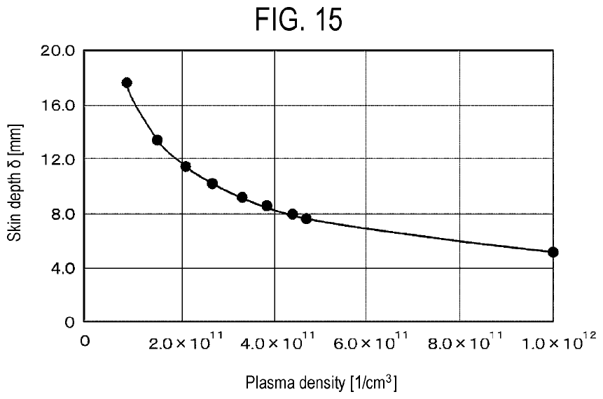

Based on the plasma density (≈electron density) measured by the experiments and calculated by the regression equation and the estimation, the skin depth δ [mm] was calculated using Equations (1) and (2) above. A correspondence relationship between the plasma density and the skin depth is illustrated in FIG. 15. It was found from these results that the skin depth δ varies in a range of approximately 5.3 to 7.8 mm when plasma is formed using the radio-frequency power in a VHF or UHF band and the plasma power in the range of 1,000 W or more and 2,500 W or less (plasma density: approximately 5.9×10¹¹ to 1.0×10¹²). Further, as described with reference to the above-described experimental results, it was found that, by setting the electrode gap G in a range of 1 to 4 times of the skin depth δ, a high-quality DLC film is obtained at a high film formation rate.

### Effects

The film forming apparatus 1 described above provides the following effects. By performing film formation under conditions that radio-frequency power in a VHF or UHF band is used and a gap distance (electrode gap) between the stage 21 and the gas shower head 3 is set to a value in a range of 1 time or more and 4 times or less of a plasma skin depth, it is possible to form a high-quality DLC film at a high film formation rate.

In particular, it has been revealed that, in the formation of the DLC film using ions, it is possible to set conditions under which good film quality and high film formation rate are achieved even in the case where a single frequency is supplied instead of the bias radio-frequency power considered necessary in the related art. When the bias radio-frequency power is not supplied, as in the film forming apparatus 1 illustrated in FIG. 1, the bias radio-frequency power supply 44 and the matcher 43 additionally provided to be connected thereto may be omitted, which makes it possible to reduce apparatus costs.

### OTHER EMBODIMENTS

The film formation gas supplied to the process container 10 to form the DLC film is not limited to the above-described examples. For example, in addition to the C₂H₂ gas, a CH₄ gas, a C₂H₄ gas, a C₃H₆ gas, a C₆H₆ gas, or a mixture gas thereof may be used as the raw material gas material of the DLC film. Further, the carbon-containing film formed on the wafer W is not limited to the DLC film containing a large number of carbon atoms with a diamond structure. For example, a carbon-containing film that contains a preset content of methyl groups (CH₃—) or methylene groups (CH₂═) may be formed on ends of carbon atoms with a diamond structure. Further, the carbon-containing film is not limited to be used as a hard mask, but may be used as a protective film, a barrier film, and a coating material.

It may be noted that the embodiments disclosed herein are exemplary in all respects and are not restrictive. The above-described embodiments may be omitted, replaced or modified in various forms without departing from the scope and spirit of the appended claims.

### EXPLANATION OF REFERENCE NUMERALS

1: Film forming apparatus, 10: Process container, 21: Stage, 3: Gas shower head, 42: Radio-frequency power supply

15-34. (canceled)

35. An apparatus for forming a carbon-containing film on a substrate, comprising:
a stage provided inside a process container and configured to serve as a lower electrode with the substrate placed thereon; and
a gas shower head serving as an upper electrode positioned to face the stage inside the process container and provided to supply a film formation gas for the carbon-containing film into the process container, the gas shower head being connected to a radio-frequency power supply configured to supply radio-frequency power in a VHF or UHF band,
wherein a gap distance between the stage and the gas shower head is set to a distance in a range of 1 time or more and 4 times or less of a skin depth of plasma of the film formation gas, which is formed by supplying the film formation gas from the gas shower head into the process container and supplying the radio-frequency power from the radio-frequency power supply to the upper electrode.

36. The apparatus of claim 35, wherein the skin depth is a value in a range of 5.3 mm to 7.8 mm, and the gap distance is a distance in a range of 6 mm to 32 mm.

37. The apparatus of claim 36, wherein the radio-frequency power in the VHF or UHF band has a frequency in a range of 30 MHz to 3 GHz.

38. The apparatus of claim 37, wherein the radio-frequency power supplied from the radio-frequency power supply is in a range of 1,000 W to 2,500 W.

39. The apparatus of claim 38, wherein a bias radio-frequency power supply configured to supply bias radio-frequency power is not connected to the lower electrode, and the lower electrode is grounded.

40. The apparatus of claim 35, wherein the lower electrode is connected to a bias radio-frequency power supply configured to supply bias radio-frequency power in a range of 3 MHz to 30 MHz, and
wherein the bias radio-frequency power supply supplies the bias radio-frequency power in a range of 400 W to 1,000 W to the lower electrode.

41. The apparatus of claim 39, wherein the carbon-containing film is a diamond-like carbon (DLC) film with a film density of 1.8 g/cm³ or higher.

42. The apparatus of claim 35, wherein the radio-frequency power in the VHF or UHF band has a frequency in a range of 30 MHz to 3 GHz.

43. The apparatus of claim 35, wherein the radio-frequency power supplied from the radio-frequency power supply is in a range of 1,000 W to 2,500 W.

44. The apparatus of claim 35, wherein a bias radio-frequency power supply configured to supply bias radio-frequency power is not connected to the lower electrode, and the lower electrode is grounded.

45. A method of forming a carbon-containing film on a substrate, the method comprising:
loading a substrate into a process container and placing the substrate on a stage, wherein the process container includes: the stage serving as a lower electrode with the substrate placed thereon; and a gas shower head serving as an upper electrode positioned to face the stage and provided to supply a film formation gas for the carbon-containing film, the gas shower head being connected to a radio-frequency power supply configured to supply radio-frequency power in a VHF or UHF band; and
subsequently, forming the carbon-containing film on the substrate by supplying the film formation gas from the gas shower head into the process container and supplying the radio-frequency power from the radio-frequency power supply to the upper electrode to plasmarize the film formation gas into plasma,
wherein a gap distance between the stage and the gas shower head is set to a distance in a range of 1 time or more and 4 times or less of a skin depth of the plasma.

46. The method of claim 25, wherein the skin depth is a value in a range of 5.3 mm to 7.8 mm, and the gap distance is a distance in a range of 6 mm to 32 mm.

47. The method of claim 26, wherein the radio-frequency power in the VHF or UHF band has a frequency in a range of 30 MHz to 3 GHz.

48. The method of claim 27, wherein the radio-frequency power supplied from the radio-frequency power supply is in a range of 1,000 W to 2,500 W.

49. The method of claim 28, wherein a bias radio-frequency power supply configured to supply bias radio-frequency power is not connected to the lower electrode, and the lower electrode is grounded.

50. The method of claim 45, wherein the lower electrode is connected to a bias radio-frequency power supply configured to supply bias radio-frequency power in a range of 3 MHz to 30 MHz, and
wherein, in the forming the carbon-containing film, the bias radio-frequency power supply supplies the bias radio-frequency power in a range of 400 W to 1,000 W to the lower electrode.

51. The method of claim 45, wherein the carbon-containing film is a diamond-like carbon (DLC) film with a film density of 1.8 g/cm³ or higher.

52. The method of claim 45, wherein the radio-frequency power in the VHF or UHF band has a frequency in a range of 30 MHz to 3 GHz.

53. The method of claim 45, wherein the radio-frequency power supplied from the radio-frequency power supply is in a range of 1,000 W to 2,500 W.

54. The method of claim 45, wherein a bias radio-frequency power supply configured to supply bias radio-frequency power is not connected to the lower electrode, and the lower electrode is grounded.
